(19) United States
(12) Patent Application Publication
(10) Pub. No.: US 2009/0308315 A1
(43) Pub. Date: Dec. 17, 2009

(54) SEMICONDUCTOR PROCESSING APPARATUS WITH IMPROVED THERMAL CHARACTERISTICS AND METHOD FOR PROVIDING THE SAME

(75) Inventor: Christianus Gerardus Maria De Ridder, Hoogland (NL)

Correspondence Address: WEINGARTEN, SCHURGIN, GAGNEBIN & LEBOVICI LLP, TEN POST OFFICE SQUARE, BOSTON, MA, 02109, US

(73) Assignee: ASM International N.V., Bilthoven (NL)

(21) Appl. No.: 12/138,909

(22) Filed: Jun. 13, 2008

(51) Int. Cl. C23C 16/00

(52) U.S. Cl. 118/715

(57) ABSTRACT

A semiconductor processing apparatus is disclosed, comprising a process chamber configured to contain a heated, gaseous atmosphere, the apparatus further comprising a number of mechanical parts, at least one of which parts is provided at least partly with a heat reflective, amorphous SiO₂ powder coating. Also disclosed is a method for treating a component of a semiconductor processing apparatus, comprising at least partly providing a surface of the component with an amorphous SiO₂ powder coating, and optionally sealing a surface of the applied coating.

### TECHNICAL FIELD

The present disclosure is directed to the field of semiconductor processing, and more in particular, to an apparatus with improved thermal characteristics and a method for providing the same.

### BACKGROUND

A semiconductor processing apparatus, such as a chemical vapor deposition apparatus for depositing films onto a substrate, may necessarily operate at a high internal temperature due to the nature of the process that the substrate is subjected to. Such a heat-intensive process is typically performed in a process chamber which is capable of sustaining a high ambient temperature. In practice, it proves difficult to prevent heat from leaking from the inside to the outside of the process chamber. Furthermore, the process chamber itself may contain mechanical components that are preferably kept at different temperatures during operation. Heat management is therefore a key aspect of good process chamber design.

Though highly insulating materials are available to control or block heat flow, many of them are not fit for use in a semiconductor processing environment. Nevertheless, attempts to this end may be made. The insulating materials may, for example, be disposed inside a process chamber within an envelope of clear fused quartz to shield them from direct contact with the atmosphere. Unfortunately, due to expanding gases inside the envelope, it is at risk of exploding when subjected to high temperatures. This risk of explosion may be avoided by providing the envelope with a so-called bleeding hole to allow for the release of the expanding gases. Because of the strongly outgassing nature of most insulating materials, however, the emitted gases are dirty in the sense that they contain particles whose presence in the controlled environment of a processing chamber is undesirable. Especially in low pressure environments, the release of polluting gases from the envelope gives rise to complications as they must be kept separated from the actual processing area. Alternatively, the envelope may be evacuated and sealed completely to prevent it from exploding. However, due to the aforesaid outgassing nature of many insulating materials, and given the risk that the envelope may develop leaks as a result of being subjected to frequent thermal cycles, this solution is better avoided as well.

It is therefore an object of the invention to provide a semiconductor processing apparatus with improved thermal characteristics, and to provide a method for providing the same.

### SUMMARY OF THE INVENTION

One aspect of the invention provides a part of, or adapted for use in, a semiconductor processing apparatus comprising a process chamber that is configured to contain a heated, gaseous process atmosphere. The part is at least partly provided with a heat reflective coating made of amorphous SiO₂ powder. The invention also provides a semiconductor processing apparatus comprising one or more of said parts.

Another aspect of the invention provides a method for treating a component of a semiconductor processing apparatus, said apparatus utilizing heated process gases and said component—during operation—being exposed to the heated process gases. The method comprises at least partly providing a surface of the component with a coating made of amorphous SiO2 powder. The method may also comprise sealing a surface of the applied coating, for example by flame polishing.

The invention will be more fully understood from the following detailed description of certain embodiments of the invention, taken together with the accompanying drawings, which are meant to illustrate and not to limit the invention.

### BRIEF DESCRIPTION OF THE DRAWINGS

FIGS. 1-4 show, schematically, a cross-sectional side view of the semiconductor processing apparatus, provided with one or more measures that improve its thermal characteristics;

FIGS. 5-6 show, schematically, a pedestal for use with the semiconductor processing apparatus of FIG. 1; and

FIG. 7 schematically illustrates two advantageous embodiments of a reflective plate for use in a semiconductor processing apparatus, such as the chemical vapor deposition apparatus shown in FIGS. 1-4.

In the drawings, the same or similar devices, parts, spaces, orientations etc. may have been indicated by the same reference numeral. Furthermore, for reasons of clarity, reference numerals in some figures may have been omitted when the object of interest is already identified in one or more preceding figures.

### DETAILED DESCRIPTION OF THE INVENTION

In a semiconductor processing apparatus according to the present disclosure, one or more mechanical parts have been treated with a coating having excellent reflective properties. The coating consists of amorphous SiO₂ powder, preferably grinded quartz material with a certain grain size and grain size distribution. As a result of the grains, the reflectivity of the coating is surprisingly high, up to 0.95 for infrared heat radiation with a wave length of 3 μm. The quartz material is compatible with semiconductor processing and is allowable in for example chemical vapor deposition reactors. To meet the surface specifications in such reactors, and to reduce the risk of outgassing of the porous coating and/or the release of particles, the surface of the coating may be sealed. This may, for example, be done by lightly flame polishing the surface. It was found that a light flame polish does not influence the reflective properties of the coating.

A commercially available coating that may be used to practice the invention is Quartz-Coat™ 850, supplied by Aremco Products Inc., located in New York, USA. An alternative commercially available coating is Hereus Quartz Coat supplied by Hereus Quartzglass GmbH & Co. K G, Hanau, Germany. The coating material is a slurry of amorphous SiO₂ powder and water. The SiO₂ powder may be formed by wet milling of SiO₂ starting grains. After applying the slurry on the part to be coated, the slurry must be dried to remove the water and then cured at high temperature, see e.g. US Patent Application Publication No. 2008/0075949.

A heat reflective coating may be applied in various thicknesses. Experiments have shown that thicknesses of 0.8 mm and above provide an average reflectivity of ≧0.95 for electromagnetic wave lengths in the range 250-2650 nm. Smaller thicknesses may be used to obtain less than maximally reflective coatings. A thickness of 0.3 mm, for example, amounts to a reflectivity of approximately 0.85. The thickness of the coating can be adapted depending on its purpose and is typically in a range between 0.05 mm to 2 mm and more preferably in a range between 0.1 and 1 mm.

Below, a number of specific applications of a heat reflective, surface-sealed glass-ceramic coating in a semiconductor processing apparatus will be discussed.

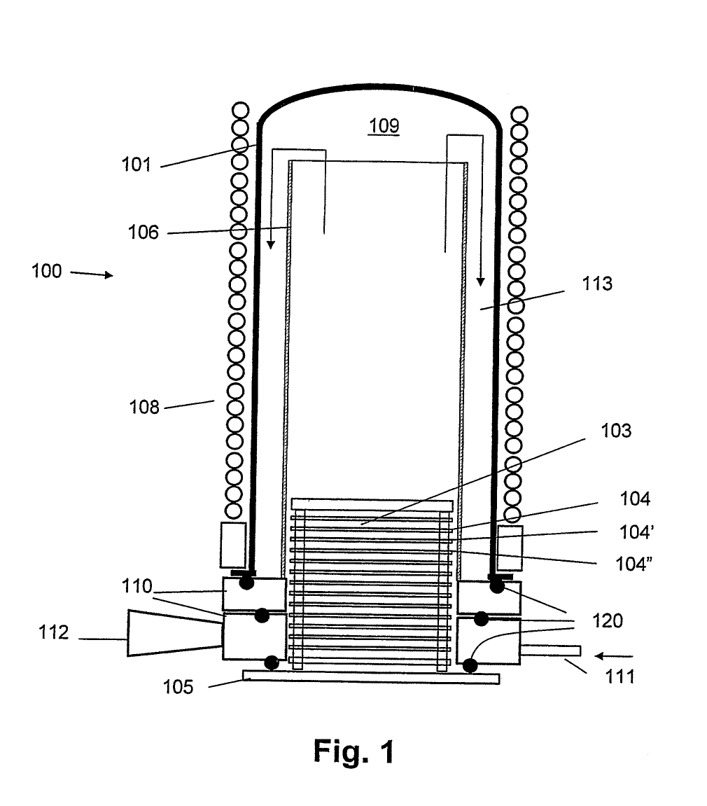

FIG. 1 shows, schematically, a cross-sectional side view of a vertical chemical vapor deposition apparatus 100. The apparatus comprises a process chamber 109, the contours of which are defined primarily by a process tube 101, which is open-ended at its bottom side, and a pedestal 103, that is removably received by the open-ended bottom part of the process tube 101. The pedestal 103 supports a wafer boat, not shown, whereas pedestal 103 is supported by a door plate 105. Process chamber 109 is surrounded by heating elements 108, such as heating coils (not shown in detail) and by insulating material, not shown. Inside process chamber 109 a liner 106 delimiting the outer perimeter of the reaction space—i.e. the core of the process chamber that, in use, contains the wafers to be processed—may be provided. Process gases and purge gas may be introduced into the reaction space through a gas feed 111, and may be exhausted from process chamber 109 via a gap 113 between liner 106 and process tube 101 through vacuum exhaust 112. Process tube 101 is supported on flanges 110. To ensure that process tube 101 is sealed in a gas-tight manner, several elastomeric O-rings 120 may be used in the lower part of reactor 100 between process tube 101, flanges 110 and door plate 105. As the reliability of elastomeric O-rings and other seals, such as V-seals, may diminish when subjected frequently or continuously to high temperatures, the lower part of reactor 100 is preferably kept at a lower temperature than that present in the central part of reaction chamber 109.

It is the pedestal's 103 primary purpose to provide thermal insulation between the process chamber 109, which in use contains a heated gaseous atmosphere, and the lower surroundings of reactor 100. In addition, it serves to reduce the temperature of any O-rings, V-seals, etc. present in the lower part of the reactor. To this end, pedestal 103 contains a number of disc shaped heat shields 104, 104′, 104″, etc., stacked vertically in a horizontal orientation. Though more heat shields do provide a higher degree of insulation, the relative scarcity of space inside reactor 100 practically limits the number of shields that may be used.

It is therefore suggested to provide the heat shields 104, 104′, 104″, etc. with the heat reflective, coating made of amorphous SiO₂ powder. A pedestal 103 including coated heat shields 104, 104′, etc. combines improved insulation. The coating may be flame polished to seal its surface in order to eliminate particle risks. Any O-rings or V-seals present in the lower area of reactor 100 will see an increase in lifetime and reliability. Furthermore, pedestal 103 may allow for larger diameter (≧450 mm) wafer reactors, as it is capable of offsetting part of the increased heat load to the lower section of the reactor that accompanies an increase in reactor diameter. Also, the pedestal 103 may be used in both low pressure and atmospheric pressure chemical vapor deposition apparatus and in atmospheric oxidation/diffusion apparatus.

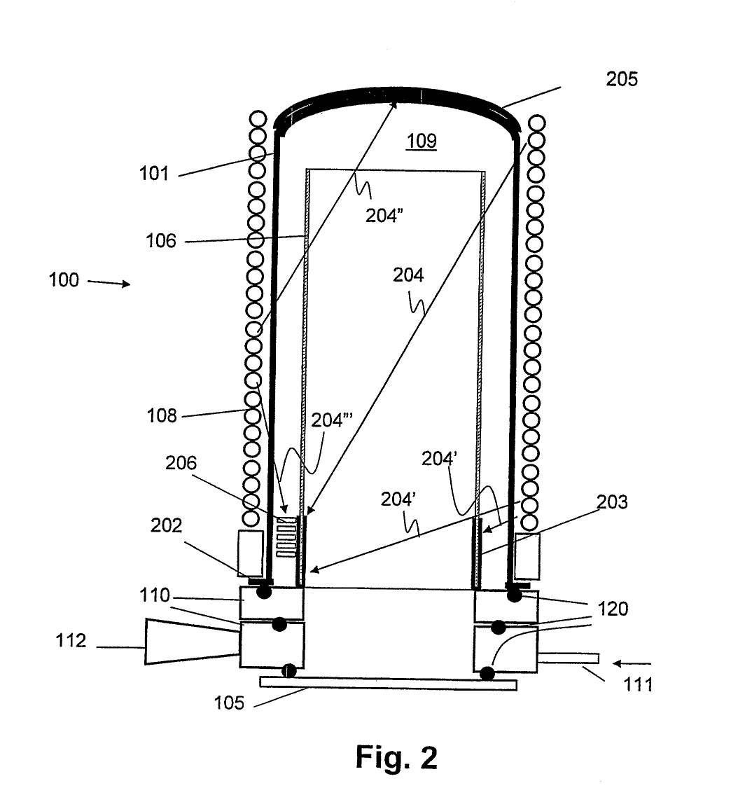

FIG. 2 shows another representation of semiconductor processing apparatus 100 of FIG. 1. In FIG. 2, pedestal 103 described above is omitted for simplicity.

In an embodiment of the invention, the heat reflective SiO₂ powder coating is applied to a lower portion 203 of liner 106. The coating may be provided on one or more of the inner surface, the outer surface and the bottom surface of the lower part of liner 106. A coating on the inner and outer surfaces reflects infrared radiation 204, 204′, 204′″ from the heating elements 108, directed at the lower section of reactor 100 that includes flanges 110, process tube flange 202 and door plate 105, which in turn enclose the O-rings 120. Providing such a coating on a liner tube 106, which may be made of clear fused quartz, is simpler and more economical than using a shorter liner and welding an opaque quartz section onto its lower end. A coating on the bottom surface of the lower part of liner 106 partly reflects heat radiation that is propagated through the body of the liner as soon as it hits the bottom surface, and thus prevents it from reaching the O-rings as well.

In another embodiment, top section 205 of process tube 101 may be provided with the heat reflective coating made of amorphous SiO₂ powder. The coating may be applied to the inside, the outside, or both sides of top section 205 of the process tube to aid in diminishing the heat loss through the top of the reactor. Optionally, traditional insulation may be provided at the outside of top section 205 as well. If the heat flux through the top of the reactor can be made sufficiently small, a separate heating zone in the top/center part of the reactor may be rendered redundant.

In yet another embodiment of the invention, coated heat shields 206 may be disposed between liner 106 and process tube 101 to reduce the radiative heat flux between the two elements, and the heat flow towards the critical O-ring areas. The depicted heat shields 206 (for clarity shown on the left side only) extend horizontally, and may be mounted in a stacked or staggering arrangement. As heat shields mounted in the space between liner 106 and process tube 101 potentially obstruct the outflow of gases, care must be taken not to position them such that they cause a pressure drop that cannot be handled properly by the vacuum pump connected to the vacuum exhaust 112.

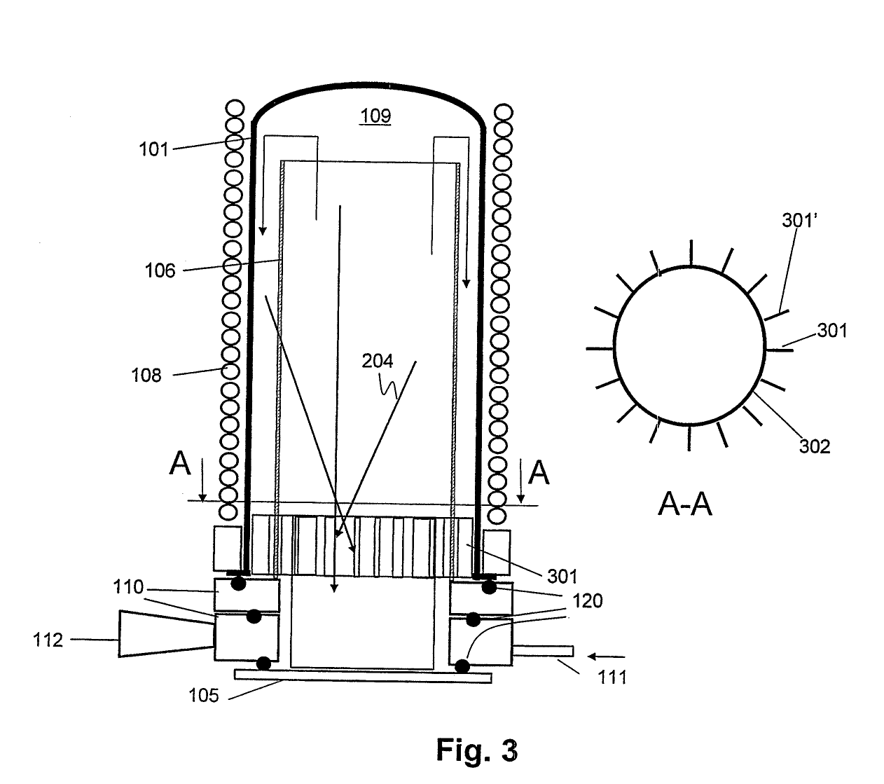

To avoid unnecessary pressure drops, the coated shields are preferably oriented vertically, like shields 301, 301′, etc. shown in FIG. 3. Said shields 301, 301′, etc. are also disposed in the annular space between liner 106 and process tube 101, and connected to a cylinder jacket 302 for structural support. Due to their vertical orientation, the shields effectively reduce the viewing angle with which the critical O-ring areas view process chamber 109 and heating elements 108 surrounding it. It is noted that the same effect may be achieved with shields that have a different shape, for example curved in stead of straight. In an alternative embodiment, shield 301, 301′ etc. may be attached to liner 106 or process tube 101.

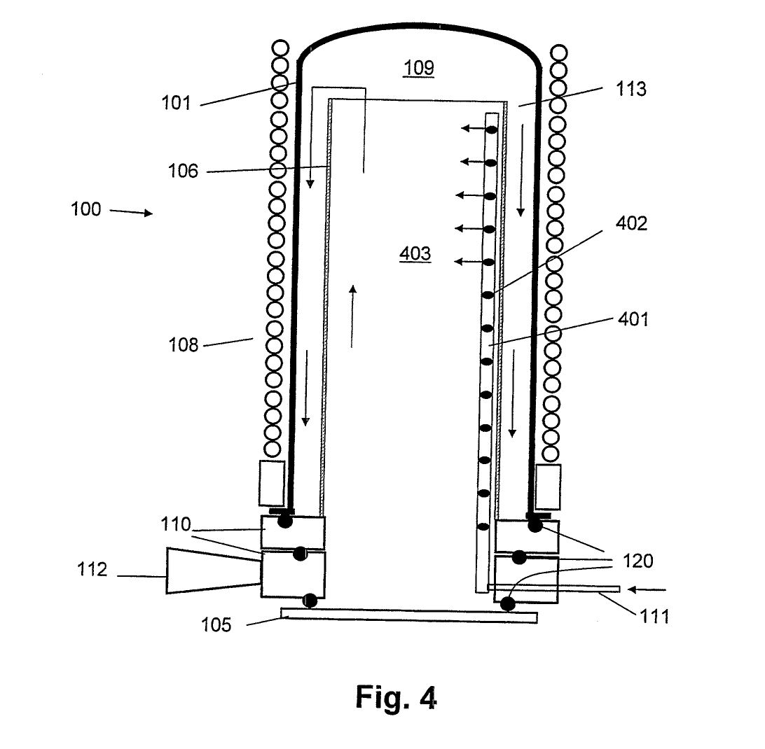

FIG. 4 schematically shows the vertical vapor deposition apparatus of FIG. 1, now supplemented with a gas injector 401 provided in process chamber 109, on the inside of liner tube 106. Gas injector 401 extends in the vertical direction over about the height of reaction area 403 and comprises a plurality of gas injection holes 402. Gas injector 401 has a feed end connected to gas feed 111 to introduce process gases and/or purge gas into reaction area 403. Said gases may be exhausted from process chamber 109 via a gap 113 between liner 106 and process tube 109 through vacuum exhaust 112.

A part of the outer surface of gas injector 401 facing reaction area 403 may be provided with the heat reflective amorphous SiO₂ powder coating. The diffuse reflection caused by the coating may be helpful in heating up gases in the lower part of the reactor. Alternatively, the outer surface area of gas injector 401 may be coated completely to prevent the injector from excessive heating. Heat radiation impinging on a completely coated gas injector 401 is reflected, while the supply of fresh gas into the injector has a cooling effect. It may be beneficial to have a temperature inside injector 401 that is slightly lower than that in process chamber 109 to prevent premature thermal decomposition of the process gases. Optionally, an additional separate closed loop cooling gas conduit may be provided inside injector 401.

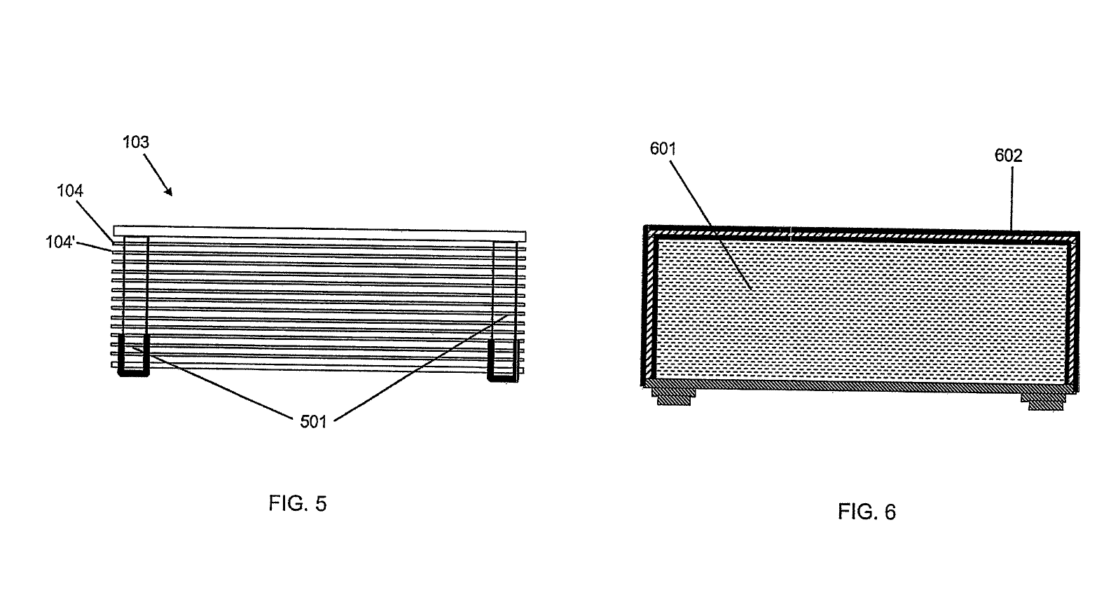

FIG. 5 schematically illustrates a pedestal 103, including a number of horizontally oriented heat shields 104, 104′, etc. The heat shields are supported by three or more legs 501 made of quartz. Two of the legs are shown schematically in FIG. 5. The feet of the legs 501 may be coated to prevent heat transfer by ‘infrared light piping’ to the lower structure supporting the pedestal, such as the door plate 105 (see FIG. 1).

FIG. 6 schematically illustrates an alternative type of pedestal, having a body 601 of insulating material. Such a pedestal is typically provided with an envelope 602 of opaque quartz. In an embodiment of the invention, envelope 602 is made of clear fused quartz, and provided with a coating of amorphous SiO₂ powder on at least one of the inside and the outside of the envelope.

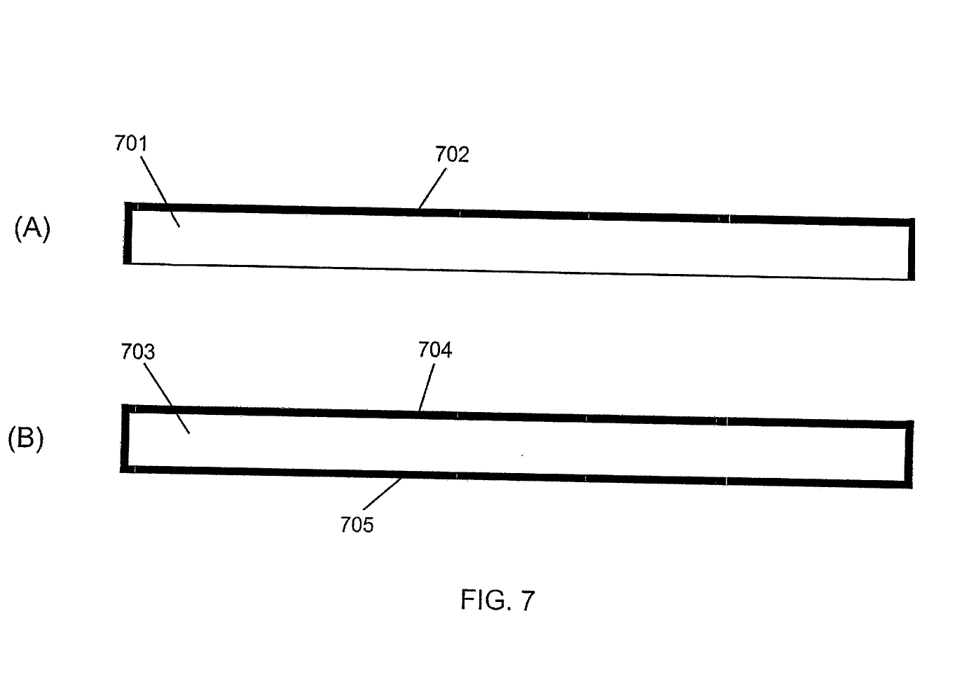

FIG. 7 schematically illustrates two advantageous embodiments of a reflective plate 701, 703 for use in a semiconductor processing apparatus. The plates 701, 703 may, for example, be used as heat shields in the pedestal 103 of the chemical vapor deposition apparatus shown in FIGS. 1-4. In a first embodiment, labeled A, reflective plate 701 is provided with the heat reflective surface-sealed glass-ceramic coating on one side 702 having a major surface area. In a second embodiment, labeled (B), plate 703 is provided with the heat reflective coating on both its major surfaces 704, 705. In the latter embodiment, the coating does not necessarily have the same thickness on both sides 704, 705. In case plate 703 is used in a pedestal 103 as described above, for example, its process chamber-facing side may be provided with a coating having a thickness that matches an average reflectivity of ≧0.95, while its door plate-facing side may be provided with a coating having a thickness that corresponds to a reflectivity between 0.20 and 0.80. In both embodiment A and B, the body of the reflective plate 701, 703 may be made of opaque or clear fused quartz material.

In an embodiment, a surface of the coating may be sealed. Although the coating itself may already be relatively non-outgassing and non-contaminating for normal use such as reflectors for lamps, it may still not be meeting the extremely stringent requirements for non-outgassing and non-particle-generation inside the processing chamber of a semiconductors processing apparatus. Sealing the coating will help to meet these stringent requirement. This may, for example, be done by lightly flame polishing the surface. It was found that a light flame polish does not influence the reflective properties of the coating.

In another embodiment a quartz plate may be disposed on a reflective plate that is provided with a reflective SiO₂ powder coating, with the quartz plate contacting the coated side of the reflective plate in sealing engagement. To this end, the edges of two plates of equal lateral dimensions may be flame polished or welded together. In this way the heat reflective coating is sandwiched between two quartz plates to avoid any potential risks of out gassing.

In an embodiment the mechanical parts may be coated partly. If, e.g. a local cold spot or hot spot is present in the reactor, a part may be partly coated to achieve the desired thermal improvement. Although the reflectivity of the coating can be tuned by adjusting the thickness of the coating, another way of tuning the reflectivity is to maintain the thickness of the coating at a constant value and to provide the coating in a pattern with a partial coverage of the surface and leaving the other part of the surface uncoated.

Although illustrative embodiments of the present invention have been described in greater detail with reference to the accompanying drawings, it is to be understood that the invention is not limited to these embodiments. Various changes or modifications may be effected by one skilled in the art without departing from the scope or the spirit of the invention as defined in the claims. Accordingly, reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that the particular features, structures, or characteristics may be combined in any suitable manner in one or more embodiments.

1. Part of, or adapted for use in, a semiconductor processing apparatus that comprises a process chamber that is configured to contain a heated, gaseous process atmosphere, wherein the part is at least partly provided with a heat reflective coating made of amorphous SiO₂ powder.

2. Part according to claim 1, wherein the part is configured to be exposed to the heated, gaseous atmosphere inside the process chamber during operation.

3. Part according to claim 1, wherein an applied heat reflective coating has a thickness between 0.05 and 2 mm.

4. Part according to claim 1, wherein an applied heat reflective coating has an average reflectivity >0.95 for electromagnetic wave lengths between 250 nm and 2650 nm.

4. Part according to claim 1, wherein a surface of the heat reflective coating has been sealed, for example by means of flame polishing.

5. Part according to claim 1, wherein the amorphous SiO₂ powder coating is Quartz-Coat™ 850 of Aremco, or Hereus Reflective Coating of Hereus.

6. Part according to claim 1, the part being a pedestal that is at least partly receivable in the process chamber, the pedestal comprising a number of heat shields at least one of which is provided with the heat reflective coating in order to direct heat into the process chamber.

7. Part according to claim 1, the part being a process tube that is configured for at least partly surrounding the process chamber.

8. Part according to claim 1, the part being a liner tube that is configured to be disposed inside the process chamber.

9. Part according to claim 1, the part being a heat shield that is configured to be disposed between a process tube and a liner tube inside the process chamber.

10. Part according to claim 1, the part being a composition of two or more quartz plates which are separated from each other by the heat reflective coating.

11. Part according to claim 1, the part being a gas injector configured to be disposed inside the process chamber.

12. Semiconductor processing apparatus comprising a process chamber that is configured to contain a heated, gaseous process atmosphere, and one or more parts according to any one of claims 1 to 11.

13. Method for treating a component of a semiconductor processing apparatus, said apparatus utilizing heated process gases and said component—during operation—being exposed to the heated process gases, comprising:
at least partly providing a surface of the component with a coating made of amorphous SiO₂ powder.

14. Method according to claim 13, wherein the surface of the reflective coating is sealed by means of flame polishing.

15. Method according to claim 13, wherein an applied coating has an average reflectivity ≧0.95 for electromagnetic wave lengths between 250 nm and 2650 nm.

16. Method according to any one of claims 13 to 15, wherein the amorphous SiO₂ powder coating is Quartz-Coat™ 850 of Aremco, or Hereus Reflective Coating of Hereus.
